(19) United States
(12) Patent Application Publication
(10) Pub. No.: US 2005/0139467 A1
(43) Pub. Date: Jun. 30, 2005

(54) Sputtering device

(76) Inventor: Nobuyuki Takahashi, Sagamihara (JP)

Correspondence Address: WENDEROTH, LIND & PONACK, L.L.P., 2033 K STREET N. W., SUITE 800, WASHINGTON, DC, 20006-1021, US

(21) Appl. No.: 11/004,871

(22) Filed: Dec. 7, 2004

(30) Foreign Application Priority Data
Dec. 24, 2003 (JP) 2003-426786

(51) Int. Cl. C23C 14/34

(52) U.S. Cl. 204/298.23; 204/298.09; 204/298.11; 204/298.28; 204/298.2

(57) ABSTRACT

A sputtering device according to this invention can sputter a plurality of substrates and can vary an angle of incidence of sputtering particles to each substrate, and comprises at least a substrate holder provided in a vacuum chamber rotatably; a plurality of substrates installed on said substrate holder; a target for forming a thin film on said substrates; and a rotatable sputtering cathode installing said target; wherein a center axis of said target is eccentric to a rotation shaft of said sputtering cathode in order to gain a desired film forming distribution.

### BACKGROUND OF THE INVENTION

The invention relates to a sputtering device including a target for forming a thin film on a plurality of substrates wherein atoms or molecules of the target are sputtered by colliding ionized gas to the target in order to form a thin film on the substrates by sticking the sputtered atoms or the molecules to the substrates.

A magnetron sputtering device disclosed in JP 2000-345336 A is such that a magnet mechanism rotating around a rotation shaft is provided in a backside of a target arranged opposite to a substrate which is a subject for forming a film, so that sputtering is carried out in a surface of the target according to magnet field generated by the magnet mechanism. Especially, the magnet mechanism is provided with an inner circumferential magnet whose shape is approximately elliptic and an outer circumferential magnet having a hollow portion surrounding the inner circumferential magnet at regular intervals, so that sputtered quantity, that is an eroded quantity, in every part of the surface of target is controlled precisely and accurately by adjusting a distance between a center position of the magnet mechanism and the rotation shaft, that is an eccentricity arrangement voluntarily.

A device for manufacturing semiconductors disclosed in JP H07-22348 A is such that a substrate holder for holding a substrate is made eccentricity from a center point in an outer circumferential direction and rotation at a film forming in order to unify a reaching quantity of sputtering particles, as a result, film thickness distribution in a metal thin film clung on the substrate may be increased. Furthermore, inclination of the substrate holder is made changing while rotation of it, so that a good coverage of the metal film can be gained by increasing the sputtering particles reaching to a tier portion and a side wall portion of each hole in the semiconductor substrate.

A sputtering device disclosed in JP 2002-20864 A is such that three distribution modifying plates which are same shapes are arranged between three circular targets and one circular substrate, and a rotation point of the revolving substrate is offset to a center of targets at a specific distance to arrange the substrate and the targets so that sputtering particles advance to the substrate obliquely.

In the device as disclosed in the above mentioned JP 2000-345336 A, though sputtering particles radiated from the target to the substrate can be poured from the whole directions at a specific angle to the substrate by rotating the magnet mechanism arranged on the backside of the target eccentrically, the target must be enlarged in the case of sputtering to a plurality of substrates, so that disadvantage such as an increase in costs of the target material and an increase of electricity is arisen.

Besides, in the device as disclosed in JP H7-22348 A, because the substrate holder is rotated eccentrically to the target, so that the target with a size covering an extent of the substrate rotation is necessary, as a result, disadvantage such as an increase of the cost of the target is arisen.

Furthermore, in the device as disclosed in JP 2002-20864 A, an incident angle of the sputtering particles to the substrate, so that it is effective in the case of forming a thin film to one substrate by sputtering a plurality of targets, but a structural problem is arisen in the case of forming thin films to a plurality of substrates.

### SUMMARY OF THE INVENTION

This invention is to provide a sputtering device wherein thin films can be formed on a plurality of substrates and an incident angle of sputtering particles to each substrate can be varied in order to gain a desirable distribution in film formation.

Accordingly, the present invention is, in a sputtering device comprising a substrate holder installed in a vacuum chamber rotatably, a plurality of substrates set on the substrate holder, a target for forming thin films on the substrates and a rotatable sputtering cathode in which the target is installed in order to form the thin films on the substrates by sputtering the target, to make a center axis of the target eccentric to a rotation shaft of the sputtering cathode.

Thus, since the center axis of the target is eccentric to the rotation shaft of the sputtering cathode, the target revolves to the substrate so as to vary its position to the substrates, so that an incidental angle of the sputtering particles to the substrate can be varied.

Besides, it is preferred that the sputtering cathode includes at least a cooling means provided on a back surface of the target, magnets for generating a magnet field on the target, and an earth shield arranged around the target, and is rotatable by a rotation means.

Furthermore, it is preferred that a shutter plate is provided between the target and the substrates movably. Accordingly, a pre-sputtering process is carried out by closing on the substrate by the shutter and sputtering, and starting and stopping of sputtering can be controlled severely.

Moreover, it is preferred that the rotation shaft of the sputtering cathode is arranged so as to position above the substrate holder. Thus, thin films can be formed on a plurality of substrates evenly.

Therefore, according to the invention, sputtering against a plurality of substrates from various directions becomes possible, so that evenness of distribution in film formation can be achieved and effective film formation can be worked.

Besides, build-up rate of film formation is increased, so that productivity can be increased.

Other and further objects, features and advantages of the invention will appear more fully from the following description.

### BRIEF DESCRIPTION OF THE DRAWINGS

FIG. 1 is a schematic diagram of a sputtering device according to an embodiment of the present invention;

FIG. 2 is an illustration showing a relationship between positions of a target and a substrate in the sputtering device of the present invention;

FIG. 3 is an illustration showing a condition such that the target is positioned most outside to a substrate holder; and

FIG. 4 is an illustration showing a condition such that the target is positioned most inside to a substrate holder.

### DETAILED DESCRIPTION OF THE INVENTION

Hereinafter, an embodiment of the present invention is explained according to referring the drawings.

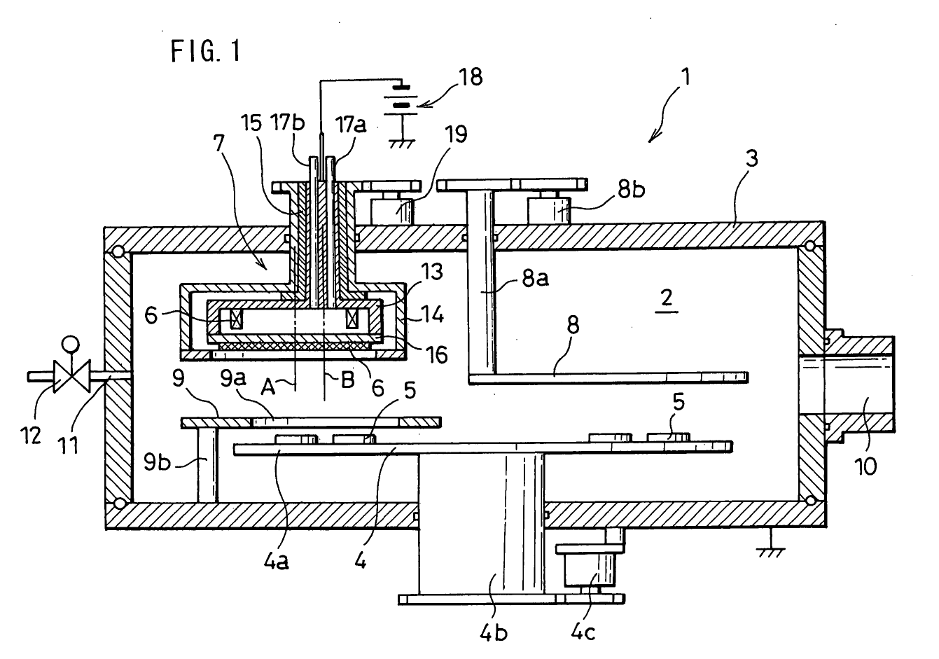

A sputtering device 1 according to an embodiment of the present invention is, as shown in FIG. 1, constituted of at least a vacuum container 3 defining a vacuum space 2 inside thereof, a substrate holder 4 arranged in the vacuum space 2, a plurality of substrates 5 set on the substrate holder 4, a target 6 arranged opposite to the substrates 5, a sputtering cathode 7 installing the target 6, a shutter plate 8 provided movably between the target 6 and the substrates 5, and a distribution controlling plate 9.

A vacuum pump not shown in figures is vacuumed through a discharge port 10 connected to the vacuum pump from an inside of the vacuum container 3 to form the vacuum space 2. Besides, a gas introducing port 11 for supplying gas such as argon gas is provided on the vacuum container 3. The gas introducing port 11 is turn on or off by a valve 12 properly.

The substrate holder 4 is constituted of a disc-like rotation carriage 4a installing the plural substrates 5, a rotation shaft 4b supporting the rotation carriage 4a, and a drive motor 4c rotating the rotation shaft 4b. Accordingly, the drive motor 4c rotates the rotation shaft 4b to rotate the rotation carriage 4a, so that the plural substrates 5 are revolved.

The distribution controlling plate 9 is provided with an opening portion 9a including substrates' revolution area, and supported by a support pole 9b so as to have a specific distance to the rotation carriage 4a of the substrate holder 4.

The sputtering cathode 7 has a rotation shaft B which is eccentric to a center axis A of the target 6. An electrode base 13 is provided around the rotation shaft B and an earth shield 14 is provided around the electrode base 13 via an insulation member 15. Furthermore, magnets 20 are insulated from the vacuum space and arranged in a rear surface of a base holder 16 which installs the target on a front surface thereof, and cooling water is supplied to the back surface of the base holder 16 via an intake 17a for introducing the cooling water and an outlet 17b for discharging the cooling water in order to prevent heat of the target 6 from increasing. Besides, the electrode base 13 is connected with one end of a sputtering power source 18 and the vacuum container 3 is connected with another end of the sputtering power source 18. Besides, the sputtering power source is a DC power source or a high-frequency power source. Furthermore, the sputtering cathode 7 can be rotated by a driving motor 19.

The shutter plate 8 is supported at a specific position by a rotating support shaft 8a, and opens or closes a front surface of the target 6 by a driving motor 8b. Besides, as the shutter plate 8 is connected with the vacuum chamber 3 electrically, the pre-sputtering can be operated by positioning the shutter plate 8 in front of the target 6, and further, starting or stopping of the sputtering operation can be controlled by opening or closing the front surface of the target 6.

In the sputtering device 1 having the above constitution, because the rotation shaft B is arranged to the center axis A of the target 6 eccentrically, it is possible that the target 6 rotates within the extent of revolving of the substrate 5 facing to the target 6.

Accordingly, a plurality of the substrates 5 are revolved at a specific speed by rotating a rotation table 4a of the substrate holder 4 and the sputtering cathode 7 is rotated at a specific speed to revolve the target 6 to the substrates 5, so that the sputtering can be operated.

Besides, a plurality of the substrates 5 are revolved at a specific speed by rotating the rotation table 4a of the substrate holder 4 and the sputtering cathode 7 is rotated and stops at a specific position to the substrates 5 to sputter the substrates at a specific time, and then, the sputtering cathode 7 is rotated to change its position again, so that the sputtering to the substrates can be carried out again.

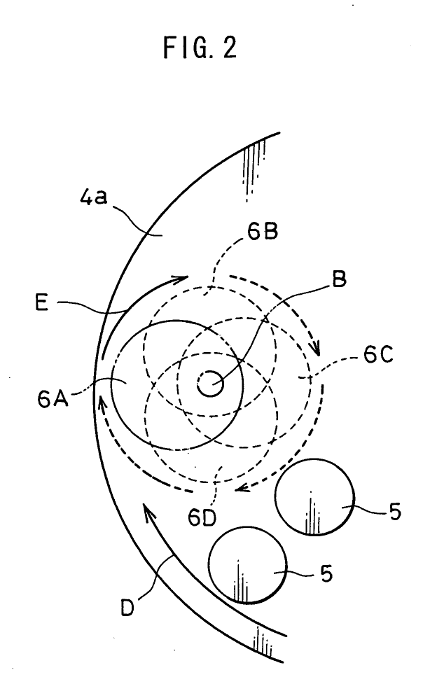

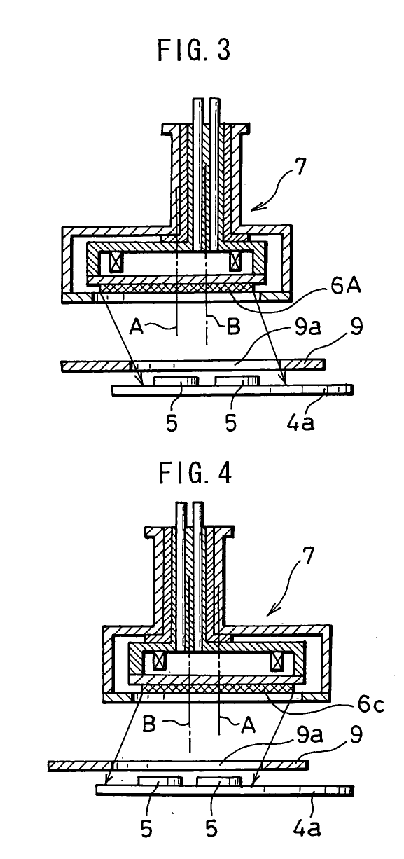

Accordingly, when the target 6 is positioned at the most outer end in a radial direction of the rotation carriage 4a by rotating the sputtering cathode 7 as shown in FIG. 2 (6A), sputtering particles sputtered form the target 6 reach to the substrate 5 in a direction slant from the outer side to the inner side in the radial direction of the rotation carriage 4a as shown in FIG. 3. Besides, when the target 6 is positioned at the most inner end in a radial direction of the rotation carriage 4a by rotating the sputtering cathode 7 as shown in FIG. 2 (6C), the sputtering particles sputtered form the target 6 reach to the substrate 5 in a direction slant from the inner side to the outer side in the radial direction of the rotation carriage 4a as shown in FIG. 4. Furthermore, when the target 6 is located at the position indicated by 6B or 6D, sputtering is carried out to the substrate 5 from a right overhead thereof.

Thus, as a angle of incidence of the sputtering particles to the substrate 5 can be varied by rotating the sputtering cathode 7, a good distribution of the film thickness and a good coverage distribution can be gained.

Moreover, as shown in FIG. 2, a rotational direction E of the sputtering cathode 7 is operated so as to correspond to a rotational direction D of the rotation carriage 4a in an outer position in the radial direction of the rotation carriage 4a, so that a relative speed between the target 6 and the substrate 5 can be decreased because the target 6 and the substrate 5 are moved in the same direction at the outer position in the radial direction of the rotation carriage 4a whose moving speed is high, and the relative speed between the target 6 and the substrate 5 can be increased because the target 6 and the substrate 5 are moved in the opposite direction at the inner position in the radial direction of the rotation carriage 4a whose moving speed is low, as a result, even adhesion of the sputtering particles can be achieved.

1. A sputtering device at least comprising:
a substrate holder provided in a vacuum chamber rotatably;
a plurality of substrates installed on said substrate holder;
a target for forming a thin film on said substrates; and
a rotatable sputtering cathode installing said target;
wherein a center axis of said target is eccentric to a rotation shaft of said sputtering cathode.

2. A sputtering device according to claim 1, wherein
said sputtering cathode comprises at least a cooling means provided behind of said target, magnets generating a magnetic field to said target and an earth shield provided around said target, and can be rotated by a rotation means.

3. A sputtering device according to claim 1, wherein
a shutter plate is provided movably between said target and said substrate.

4. A sputtering device according to claim 1, wherein
a distribution controlling plate with a specific opening is arranged between said target and said substrate.

5. A sputtering device according to claim 1, wherein
said rotation shaft is arranged so as to position above said substrate holder.

6. A sputtering device according to claim 2, wherein
a shutter plate is provided movably between said target and said substrate.

7. A sputtering device according to claim 2, wherein
a distribution controlling plate with a specific opening is arranged between said target and said substrate.

8. A sputtering device according to claim 2, wherein
said rotation shaft is arranged so as to position above said substrate holder.

9. A sputtering device according to claim 3, wherein
a distribution controlling plate with a specific opening is arranged between said target and said substrate.

10. A sputtering device according to claim 3, wherein
said rotation shaft is arranged so as to position above said substrate holder.

11. A sputtering device according to claim 4, wherein
said rotation shaft is arranged so as to position above said substrate holder.

12. A sputtering device according to claim 6, wherein
a distribution controlling plate with a specific opening is arranged between said target and said substrate.

13. A sputtering device according to claim 6, wherein
said rotation shaft is arranged so as to position above said substrate holder.

14. A sputtering device according to claim 7, wherein
said rotation shaft is arranged so as to position above said substrate holder.

15. A sputtering device according to claim 9, wherein
said rotation shaft is arranged so as to position above said substrate holder.

15. A sputtering device according to claim 12, wherein
said rotation shaft is arranged so as to position above said substrate holder.
